(19) United States
(12) Patent Application Publication
(10) Pub. No.: US 2024/0324383 A1
(43) Pub. Date: Sep. 26, 2024

(54) DISPLAY APPARATUS

(71) Applicant: Samsung Display Co., Ltd., Yongin-si (KR)

(72) Inventors: Hyungue Kim, Yongin-si (KR); Guanghai Jin, Yongin-si (KR)

(73) Assignee: Samsung Display Co., Ltd., Yongin-si (KR)

(21) Appl. No.: 18/613,604

(22) Filed: Mar. 22, 2024

(30) Foreign Application Priority Data
Mar. 24, 2023 (KR) 10-2023-0038992
Apr. 27, 2023 (KR) 10-2023-0055656

(51) Int. Cl. H10K 59/35

(52) U.S. Cl. CPC H10K 59/353; H10K 59/352

(57) ABSTRACT

A display apparatus includes a first reference sub-pixel emitting light in a first wavelength band and having a polygonal shape in a plan view, a first sub-pixel emitting light in a second wavelength band and having a first shape in a plan view defined by a portion of imaginary circles each having a radius and a center disposed on a side of the polygonal shape, and a second sub-pixel emitting light in a third wavelength band and having a second shape in a plan view defined by another portion of the imaginary circles.

### CROSS REFERENCE TO RELATED APPLICATION(S)

This application claims priority to and benefits of Korean Patent Application No. 10-2023-0038992 under 35 U.S.C. § 119, filed on Mar. 24, 2023, and Korean Patent Application No. 10-2023-0055656 under 35 U.S.C. § 119, filed on Apr. 27, 2023, in the Korean Intellectual Property Office (KIPO), the entire contents of which are incorporated herein by reference.

### BACKGROUND

### 1. Technical Field

Embodiments relate to a display apparatus having a high aperture ratio.

### 2. Description of the Related Art

A display apparatus is an apparatus that receives information about an image and displays the image. Display apparatuses may be used as a display part of small products, such as mobile phones or the like, or as a display part of large products, such as televisions or the like.

A display apparatus includes multiple pixels that receive an electrical signal and emit light to display an image. Each pixel includes a light-emitting element, for example, an organic light-emitting diode (OLED) of an organic light-emitting display apparatus. In general, in an organic light-emitting display apparatus, a thin-film transistor and an OLED are formed on a substrate, and the OLED operates by emitting light.

In order to improve an image quality and an energy efficiency of display apparatuses, an aperture ratio of a pixel needs to be increased.

### SUMMARY

The disclosure provides a display apparatus having a high aperture ratio. However, this objective is merely illustrative, and the scope of the disclosure is not limited thereto.

Additional aspects will be set forth in part in the description which follows and, in part, will be apparent from the description, or may be learned by practice of embodiments of the disclosure.

According to the disclosure, a display apparatus may include a first reference sub-pixel emitting light in a first wavelength band and having a polygonal shape in a plan view, a first sub-pixel emitting light in a second wavelength band and having a first shape in a plan view defined by a portion of imaginary circles having a radius and a center disposed on a side of the polygonal shape, and a second sub-pixel emitting light in a third wavelength band and having a second shape in a plan view defined by another portion of the imaginary circles.

The first reference sub-pixel may be spaced apart from the first sub-pixel and the second sub-pixel by the radius.

A polygonal shape of the first reference sub-pixel may include at least one obtuse angle, a first-first line segment having a first length, and a first-second line segment having a second length that is less than the first length.

A center of the first sub-pixel and a center of the second sub-pixel may be arranged on a first imaginary axis, and the first shape of the first sub-pixel may include a first-first line corresponding to the first-first line segment, and a first-first corner connected to the first-first line and protruding toward the second sub-pixel along the first imaginary axis.

The first-first line may contact one of the imaginary circles having center disposed on the first-first line segment.

The first-first corner may be partially defined by a first-first curve that is bent in a curvature of a circumference of one of the imaginary circles having center disposed on a first-first vertex of the first reference sub-pixel.

The first-first vertex may be disposed closest to the first-first corner among vertexes of the polygonal shape of the first reference sub-pixel in a plan view.

The display apparatus may further include a second reference sub-pixel having the polygonal shape in a plan view, spaced apart from the first sub-pixel and the second sub-pixel by the radius, and being symmetrical to the first reference sub-pixel based on the first imaginary axis.

The first-first corner may be partially defined by a first-second curve that is bent along a curvature of a circumference of one of the imaginary circles having center disposed on a second-first vertex of the second reference sub-pixel.

The second-first vertex may be disposed closest to the first-first corner among vertexes of the polygonal shape of the second reference sub-pixel in a plan view.

The first-first corner may include the first-first curve, the first-second curve, and a first-third curve connecting the first-first curve and the first-second curve to each other and being convex.

The polygonal shape may include a long axis and a short axis intersecting the long axis in a plan view.

The polygonal shape may include an octagonal shape.

A center of the first sub-pixel and a center of the second sub-pixel may be arranged on a first imaginary axis, and the second shape of the second sub-pixel may include a second-first line corresponding to the first-second line segment, and a second-first corner connected to the second-first line and protruding toward the first sub-pixel along the first imaginary axis.

The second-first line may contact one of the imaginary circles having center disposed on an origin on the first-second line segment.

The second-first corner may be partially defined by a second-first curve that is bent in a curvature of a circumference of one of the imaginary circles having a center disposed on a first-second vertex of the first reference sub-pixel.

The first-second vertex may be disposed closest to the second-first corner among vertexes of the polygonal shape of the first reference sub-pixel in a plan view.

The display apparatus may further include a second reference sub-pixel having the polygonal shape in a plan view, spaced apart from the first sub-pixel and the second sub-pixel by the radius, and being symmetrical to the first reference sub-pixel based on the first imaginary axis.

The second-first corner may be partially defined by a second-second curve, which is bent along a curvature of a circumference of one of the imaginary circles having a center disposed on a second-second vertex of the second reference sub-pixel.

The second-second vertex may be disposed closest to the second-first corner among vertexes of the polygonal shape of the second reference sub-pixel in a plan view.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic plan view illustrating a display panel of a display apparatus according to an embodiment;

FIG. 2 is a schematic diagram of an equivalent circuit of a pixel of the display panel of FIG. 1;

FIG. 3 is a schematic cross-sectional view illustrating a part of the display panel of FIG. 1;

FIG. 4 is a schematic plan view illustrating sub-pixels of region A of FIG. 1;

FIG. 5 is a schematic plan view illustrating sub-pixels of region A1 of FIG. 4; and

FIGS. 6 and 7 are schematic plan views illustrating sub-pixels arranged in region A1-1 of FIG. 5.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, an embodiment is merely described below, by referring to the figures, to explain aspects of the description.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the x direction, the y-axis direction, and the z-axis direction are not limited to three axes of a rectangular coordinate system, such as the x, y, and z-axes directions, and may be interpreted in a broader sense. For example, the x-axis direction, the y-axis direction, and the z-axis direction may be perpendicular to one another, or may represent different directions that are not perpendicular to one another.

It will be understood that when an element such as a layer, film, region, or substrate is referred to as being “on” or “above” another element, it can be directly on the other element or intervening element(s) may also be present. In contrast, when an element is referred to as being “directly on” another element, no intervening elements are present.

Spatially relative terms, such as “above,” “upper,” “over,” and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

When a component is described herein to “connect” another component to the other component or to be “connected to” other components, the components may be connected to each other as separate elements, or the components may be integral with each other.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

As used herein, the term “and/or” includes any and all combinations of at least one of the associated listed items. For example, “a and/or b” may be understood to mean “a, b, or a and b.” The terms “and” and “or” may be used in the conjunctive or disjunctive sense and may be understood to be equivalent to “and/or.” Throughout the disclosure, the expression “at least one of a, b, and c” indicates only a, only b, only c, both a and b, both a and c, both b and c, all of a, b, and c, or variations thereof. Also, “at least two of x, y, and z,” may be construed as two or more of x, y, and z such as both x and y, both x and z, both y and z, both x, y, and z.

Since various modifications and various embodiments of the disclosure are possible, specific embodiments are illustrated in the drawings and described in detail in the detailed description. Effects and features of the disclosure, and a method of achieving them will be apparent with reference to embodiments described below in detail in conjunction with the drawings. However, the disclosure is not limited to an embodiment disclosed herein but may be implemented in a variety of forms.

Hereinafter, embodiments of the disclosure will be described in detail with reference to the accompanying drawings, and the same or corresponding components are denoted by the same reference numerals, and the same reference numerals are assigned and redundant explanations will be omitted.

In the following embodiments, when a portion such as a layer, a film, a region, a plate, or the like is on other portions, this is not only when the portion is on other elements, but also when other elements are interposed therebetween. In the drawings, for convenience of explanation, the sizes of elements may be exaggerated or reduced. For example, since the size and thickness of each component shown in the drawings are arbitrarily indicated for convenience of explanation, the disclosure is not necessarily limited to the illustration.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The x-axis, the y-axis, and the z-axis are not limited to three axes on a Cartesian coordinate system, and may be interpreted in a broad sense including the same. For example, the x-axis, the y-axis, and the z-axis may be perpendicular to each other, but may refer to different directions that are not orthogonal to each other.

The display surface may be parallel to a surface defined by an x-axis direction and a y-axis direction. A normal direction of the display surface, i.e., a thickness direction of the display apparatus, may indicate a z-axis direction. In this specification, an expression of “when viewed from the top or in a plan view” may represent a case when viewed in the z-axis direction. Hereinafter, a front surface (or a top surface) and a rear surface (or a bottom surface) of each of layers or units may be distinguished by the z-axis direction. However, directions indicated by the x, y, z-axes directions may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a display apparatus according to an embodiment will be described based on the above description in detail as follows.

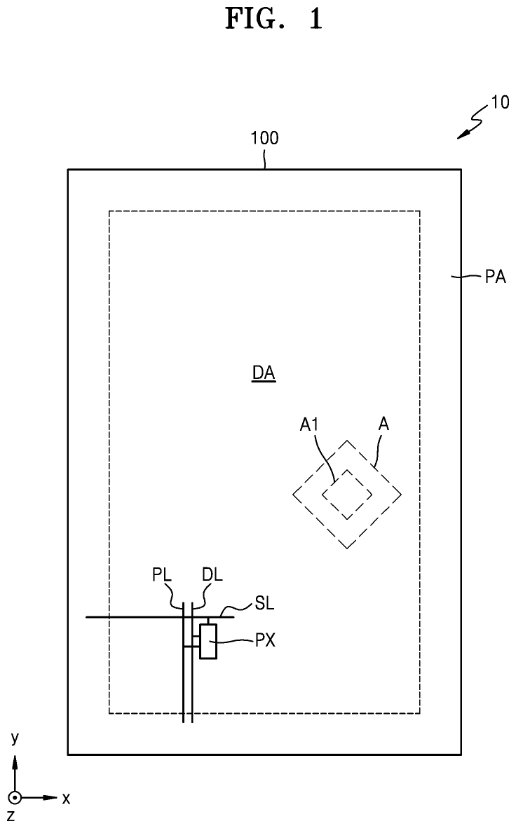

FIG. 1 is a schematic plan view illustrating a display panel of a display apparatus according to an embodiment.

As illustrated in FIG. 1, a display apparatus according to an embodiment may include a display panel 10. For example, the display apparatus may be a variety of apparatuses, such as smartphones, tablets, laptops, televisions, billboards, or the like. The display apparatus according to an embodiment may include thin-film transistors, capacitors, and/or the like, and the thin-film transistors, the capacitors, and/or the like may be implemented by conductive layers and insulating layers.

The display panel 10 may include a display area DA, and a peripheral area PA disposed adjacent to the display area DA. For example, the peripheral area PA may surround the display area DA in a plan view. FIG. 1 illustrates that the display area DA has a rectangular shape in a plan view. However, the disclosure is not limited thereto. The display area DA may have various shapes, such as a circular shape, an elliptical shape, a polygonal shape, a shape of a specific figure, and the like in a plan view.

The display area DA may be a portion in which an image is displayed, and multiple pixels PX may be arranged in the display area DA. Each of the pixels PX may include a display element such as an organic light-emitting diode or the like. Each pixel PX may emit red, green, or blue light, for example. The pixel PX may be electrically connected to a pixel circuit including a thin-film transistor (TFT), a storage capacitor, and the like. The pixel circuit may be electrically connected to a scan line SL that transmits a scan signal, a data line DL that intersects the scan line SL and transmits a data signal, and a driving voltage line PL that supplies a driving voltage. The scan line SL may extend in an x-axis direction (hereinafter, a second direction), and the data line DL and the driving voltage line PL may extend in a y-axis direction (hereinafter, a first direction).

The pixel PX may emit light with a luminance corresponding to an electrical signal from the pixel circuit electrically connected to the pixel PX. In the display area DA, an image (e.g., a certain or selectable image) may be displayed through light emitted from the pixel PX. In an embodiment, the pixel PX may be a light-emitting area in which light of one of red, green, and blue is emitted, as described above.

The peripheral area PA may be an area in which the pixel PX is not disposed, and an area in which no image is displayed. A power supply wiring for driving the pixel PX may be disposed in the peripheral area PA. Multiple pads may be arranged in the peripheral area PA, and a printed circuit board including a driving circuit part or an integrated circuit (IC) element such as a driver IC or the like may be disposed be arranged in the peripheral area PA and electrically connected to the pads.

The display panel 10 may include a substrate 100, and the substrate 100 may include the display area DA and the peripheral area PA. The substrate 100 will be described in detail below.

Multiple transistors may be arranged in the display area DA. In the transistors, according to a type of a transistor (N-type or P-type) and/or operation conditions, a first terminal of a transistor may be one of a source electrode and a drain electrode, and a second terminal of the transistor may be another one of the source electrode and the drain electrode. For example, in case that the first terminal is a source electrode, the second terminal may be a drain electrode.

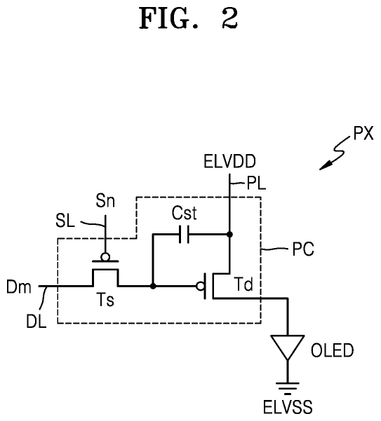

The transistors may include a driving transistor, a data writing transistor, a compensation transistor, an initialization transistor, an emission control transistor, or the like. The driving transistor may be electrically connected between the driving voltage line PL and an organic light-emitting diode (see, e.g., OLED of FIG. 2), and the data writing transistor may be electrically connected to the data line DL and the driving transistor and may perform a switching operation for transmitting a data signal transmitted from the data line DL.

The compensation transistor may be turned on in response to the scan signal received through the scan line SL and electrically connect the driving transistor and the organic light-emitting diode OLED to each other, thereby compensating for a threshold voltage of the driving transistor.

The initialization transistor may be turned on in response to the scan signal received through the scan line SL and transmit an initialization voltage to a gate electrode of the driving transistor, thereby initializing the gate electrode of the driving transistor. The scan line electrically connected to the initialization transistor and the scan line electrically connected to the compensation transistor may be different from each other.

The emission control transistor may be turned on in response to the emission control signal received through the emission control line, and as a result, a driving current may flow through the organic light-emitting diode OLED.

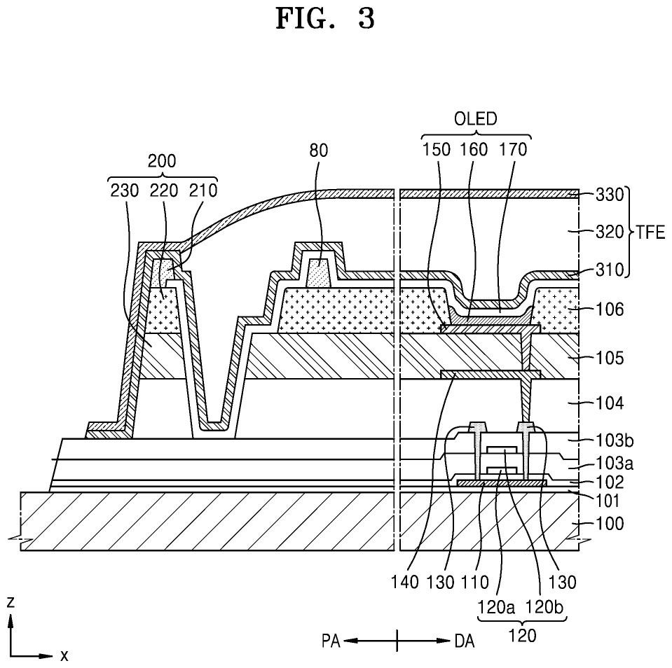

The organic light-emitting diode OLED may include a pixel electrode (anode) and an opposite electrode (cathode), and a second driving voltage ELVSS may be applied to the opposite electrode (see, e.g., 170 of FIG. 3). The organic light-emitting diode OLED may receive a driving current from the driving transistor and emit light, thereby displaying an image.

Hereinafter, an organic light-emitting display apparatus will be described as a display apparatus according to an embodiment. However, the display apparatus of the disclosure is not limited thereto. In another embodiment, the display apparatus of the disclosure may be an inorganic light-emitting display apparatus, inorganic electroluminescent (EL) display apparatus, a quantum dot light-emitting display apparatus, or the like. For example, a light-emitting layer of a display element of the display apparatus may include an organic material or an inorganic material. The display apparatus may include a light-emitting layer, and quantum dots disposed on a path of light emitted from the light-emitting layer.

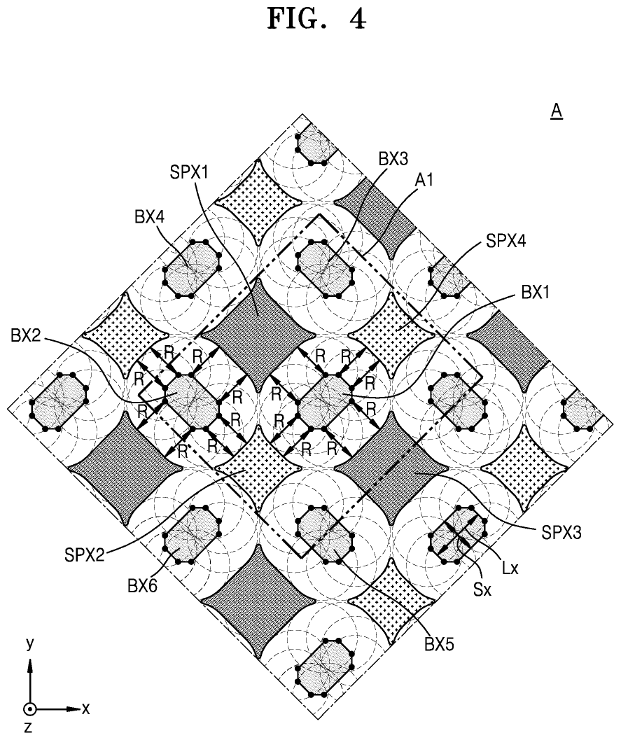

As illustrated in FIG. 1, in the display panel 10, the display area DA may include region A and region A1 inside the region A. The pixel PX arranged in region A and region A1 inside the region A will be described with reference to FIG. 4 and the like below.

FIG. 2 is a schematic diagram of an equivalent circuit of a pixel of the display panel of FIG. 1.

As illustrated in FIG. 2, each pixel PX may include a pixel circuit PC electrically connected to a scan line SL and a data line DL, and an organic light-emitting diode OLED electrically connected to the pixel circuit PC.

The pixel circuit PC may include a driving thin-film transistor Td, a switching thin-film transistor Ts, and a storage capacitor Cst. The switching thin-film transistor Ts may be electrically connected to the scan line SL and the data line DL and may transmit a data signal Dm inputted through the data line DL to the driving thin-film transistor Td in response to the scan signal Sn inputted through the scan line SL.

The storage capacitor Cst may be electrically connected to the switching thin-film transistor Ts and the driving voltage line PL and may store a voltage corresponding to a difference between a voltage transmitted from the switching thin-film transistor Ts and a first power supply voltage ELVDD supplied to the driving voltage line PL.

A second power supply voltage ELVSS may be lower than the first power supply voltage ELVDD. The level of a driving voltage supplied to each pixel PX may be a voltage difference between the level of the first power supply voltage ELVDD and the level of the second power supply voltage ELVSS.

The driving thin-film transistor Td may be electrically connected to the driving voltage line PL and the storage capacitor Cst, and may control a driving current flowing to the organic light-emitting diode OLED from the driving voltage line PL in response to a voltage value stored in the storage capacitor Cst. The organic light-emitting diode OLED may cmit light having a luminance (e.g., certain or selectable luminance) according to the driving current.

FIG. 2 illustrates that the pixel circuit PC includes two thin-film transistors and one storage capacitor, but the disclosure is not limited thereto. In an embodiment, the pixel circuit PC may include more than two storage capacitors.

FIG. 3 is a schematic cross-sectional view illustrating a part of the display panel of FIG. 1.

The substrate 100 may include areas corresponding to the display area DA and the peripheral area PA disposed adjacent to the display area DA, as described above. The substrate 100 may include various materials having flexible or bendable characteristics. In an embodiment, the substrate 100 may include glass, metal, a polymer resin, or the like. In an embodiment, the substrate 100 may include a polymer resin including polyethersulfone, polyacrylate, polyether imide, polyethylene naphthalate, polyethylene terephthalate, polyphenylene sulfide, polyarylate, polyimide, polycarbonate, cellulose acetate propionate, the like, or a combination thereof. However, the disclosure is not limited thereto, and the substrate may include various material. In an embodiment, the substrate 100 may have a multi-layered structure, including two layers each including the polymer resin and a barrier layer including an inorganic material (such as silicon oxide, silicon nitride, silicon oxynitride, or the like) interposed between the layers.

A buffer layer 101 may be disposed on the substrate 100. The buffer layer 101 may prevent impurity ions from being diffused, may prevent penetration of moisture or outside air, and may serve as a barrier layer and/or a blocking layer for planarizing a surface (e.g., a top surface of the buffer layer 101). The buffer layer 101 may include silicon oxide, silicon nitride, silicon oxynitride, the like, or a combination thereof. The buffer layer 101 may regulate a heat transfer rate during a crystallization process to form a semiconductor layer 110, so that the semiconductor layer 110 may be uniformly crystallized.

The semiconductor layer 110 may be disposed on the buffer layer 101. The semiconductor layer 110 may include polysilicon or the like, and may include a channel region in which impurities are not doped, and a source region and a drain region, each disposed at each side of the channel region and doped with an impurity. The impurities may vary according to the type of thin-film transistors and may be an N-type impurity or a P-type impurity.

A gate insulating layer 102 may be disposed on the semiconductor layer 110. The gate insulating layer 102 may secure an insulation property between the semiconductor layer 110 and a gate layer 120 (e.g., a first gate layer 120a). The gate insulating layer 102 may include an inorganic material, such as silicon oxide, silicon nitride, silicon oxynitride, the like, or a combination thereof, and may be disposed between the semiconductor layer 110 and the gate layer 120. The gate insulating layer 102 may have a shape corresponding to a surface (e.g., an entire surface) of the substrate 100, and may have a structure in which contact holes are formed in a portion (e.g., a preset portion) of the gate insulating layer 102. The gate insulating layer 102 including the inorganic material may be formed through chemical vapor deposition (CVD), atomic layer deposition (ALD), or the like. This is also applied to the following embodiments and modifications thereof.

The gate layer 120 may include a first gate layer 120a and a second gate layer 120b. The first gate layer 120a may be disposed on the gate insulating layer 102. The first gate layer 120a may overlap the semiconductor layer 110 vertically (e.g., in a z-axis direction), and may include at least one of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

A first interlayer insulating layer 103a may be disposed on the first gate layer 120a. The first interlayer insulating layer 103a may cover the first gate layer 120a. The first interlayer insulating layer 103a may include an inorganic material. For example, the first interlayer insulating layer 103a may include metal oxide, metal nitride, or the like. For example, the first interlayer insulating layer 103a may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZrO₂), the like, or a combination thereof. The first interlayer insulating layer 103a may have a double structure of SiOₓ/SiN_{y}, SiNₓ/SiO_{y}, or the like in embodiments.

The second gate insulating layer 120b may be disposed on the first interlayer insulating layer 103a. The second gate layer 120b may overlap the first gate layer 120a vertically (e.g., in a z-axis direction), and may include at least one of Mo, Al, Pt, Pd, Ag, Mg, Au, Ni, Nd, Ir, Cr, Li, Ca, Ti, W, and Cu.

The second gate layer 120b may constitute the storage capacitor (see, e.g., Cst of FIG. 2), with the first gate layer 120a. The first gate layer 120a may be an electrode of the storage capacitor Cst, and the second gate layer 120b may be another electrode of the storage capacitor Cst.

In a plan view, an area of the second gate layer 120b may be greater than an area of the first gate layer 120a. In another embodiment, in a plan view, the second gate layer 120b may cover the first gate layer 120a.

A second interlayer insulating layer 103b may be disposed on the second gate layer 120b. The second interlayer insulating layer 103b may cover the second gate layer 120b. The second interlayer insulating layer 103b may include an inorganic material. For example, the second interlayer insulating layer 103b may include metal oxide, metal nitride, or the like. For example, the second interlayer insulating layer 103b may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZrO₂), the like, or a combination thereof. The second interlayer insulating layer 103b may have a double structure of SiOₓ/SiN_{y} or SiNₓ/SiO_{y} in embodiments.

A first conductive layer 130 may be disposed on the second interlayer insulating layer 103b. The first conductive layer 130 may be an electrode electrically connected to a source or drain region of a semiconductor layer through a through hole included in the second interlayer insulating layer 103b. The first conductive layer 130 may include at least one of Al, Pt, Pd, Ag, Mg, Au, Ni, Nd, Ir, Cr, Li, Ca, Mo, Ti, W, and Cu. For example, the first conductive layer 130 may include a Ti layer, an Al layer, a Cu layer, the like, or a combination thereof.

A first organic insulating layer 104 may be disposed on the first conductive layer 130. The first organic insulating layer 104 may be an organic insulating layer that covers an upper portion of the first conductive layer 130, has a substantially flat upper surface, and serves as a planarization layer. The first organic insulating layer 104 may include an organic material, such as an acrylic material, benzocyclobutene (BCB), hexamethyldisiloxane (HMDSO), or the like. The first organic insulating layer 104 may be variously modified and may have a single layer or multi-layered structure.

A second conductive layer 140 may be disposed on the first organic insulating layer 104. The second conductive layer 140 may be an electrode connected to a source or drain region of a semiconductor layer through a through hole included in the first organic insulating layer 104. The second conductive layer 140 may include at least one of Al, Pt, Pd, Ag, Mg, Au, Ni, Nd, Ir, Cr, Li, Ca, Mo, Ti, W, and Cu. For example, the second conductive layer 140 may include a Ti layer, an Al layer, a Cu layer, the like, or a combination thereof.

A second organic insulating layer 105 may be disposed on the first conductive layer 130. The second organic insulating layer 105 may be an organic insulating layer that covers an upper portion of the first conductive layer 130, has a substantially flat upper surface, and serves as a planarization layer. The second organic insulating layer 105 may include an organic material such as an acrylic material, BCB, HMDSO, or the like. The second organic insulating layer 105 may be variously modified and may have a single layer or multi-layered structure.

Although not shown in FIG. 3, an additional conductive layer and an additional insulating layer may be disposed between the conductive layer (e.g., the first conductive layer 130, the second conductive layer 140) and a pixel electrode 150, and may be applied in various embodiments. The additional conductive layer and the conductive layer (e.g., the first conductive layer 130, the second conductive layer 140) may include a same material, and may have a same layer structure. The additional insulating layer and the organic insulating layer (e.g., the first organic insulating layer 104, the second organic insulating layer 105) may include a same material, and may have a same layer structure.

The pixel electrode 150 may be disposed on the second organic insulating layer 105. The pixel electrode 150 may be electrically connected to the second conductive layer 140 through a contact hole formed in the second organic insulating layer 105. A display element may be disposed on the pixel electrode 150. The organic light-emitting diode OLED may be the display element. For example, the organic light-emitting diode OLED may be disposed on the pixel electrode 150. The pixel electrode 150 may include a transparent conductive layer formed of a transparent conductive oxide such as ITO, In₂O₃, IZO, or the like, and a reflective layer formed of a metal such as Al, Ag, or the like. For example, the pixel electrode 150 may have a three-layer structure of ITO/Ag/ITO.

A pixel-defining layer 106 may be disposed on the second organic insulating layer 105 and may cover both edges of the pixel electrode 150. For example, the pixel-defining layer 106 may cover both edges of the pixel electrode 150. The pixel-defining layer 106 may have an opening corresponding to the pixel PX, the opening may be formed, and at least a center portion of the pixel electrode 150 may be exposed. The pixel-defining layer 106 may include an organic material such as polyimide, HMDSO, or the like. A spacer 80 may be disposed on the pixel-defining layer 106.

The spacer 80 may be disposed in the peripheral area PA but may also be disposed in the display area DA. The spacer 80 may prevent the organic light-emitting diode OLED from being damaged by sagging of a mask in a manufacturing process using the mask. The spacer 80 may include an organic insulating material or the like, and may have a single layer or multi-layered structure.

An intermediate layer 160 and an opposite electrode 170 may be disposed in the opening of the pixel-defining layer 106. The intermediate layer 160 may include a low molecular weight material, polymer material, or the like, and in case that the intermediate layer 160 includes a low molecular weight material, the intermediate layer 160 may include a hole injection layer (HIL), a hole transport layer (HTL), an emission layer, an electron transport layer (ETL), an electron injection layer (EIL), the like, or a combination thereof. In case that the intermediate layer 160 includes a polymer material, the intermediate layer 160 may have a structure that generally includes an HTL, an emission layer, and the like.

The opposite electrode 170 may include a transparent conductive layer formed of a transparent conductive oxide such as ITO, In₂O₃. IZO, or the like. The pixel electrode 150 may be an anode, and the opposite electrode 170 may be a cathode. In another embodiment, a polarity of electrodes may be reversed. For example, the pixel electrode 150 may be a cathode, and the opposite electrode 170 may be an anode.

A structure of the intermediate layer 160 is not limited to the above description, and may have various structures. For example, at least one of layers forming the intermediate layer 160 may be integrally formed, as in the opposite electrode 170. In another embodiment, the intermediate layer 160 may include a layer patterned and correspond to each of the pixel electrodes 150.

The opposite electrode 170 may be arranged on the display area DA and may be arranged throughout the display area DA. For example, the opposite electrode 170 may be integrally formed and cover multiple pixels (see, e.g., PX of FIG. 2). The opposite electrode 170 may electrically contact a common power supply line (not shown) disposed in the peripheral area PA. In an embodiment, the opposite electrode 170 may extend to a barrier wall 200. A thin-film encapsulation layer TFE may cover a whole of the display area DA, may extend to the peripheral area PA, and may cover at least a part of the peripheral area PA.

The thin-film encapsulation layer TFE may extend to an outside of the common power supply line (not shown). The thin-film encapsulation layer TFE may include a first inorganic encapsulation layer 310, a second inorganic encapsulation layer 330, and an organic encapsulation layer 320 interposed the first inorganic encapsulation layer 310 and the second inorganic encapsulation 330. The first inorganic encapsulation layer 310 and the second inorganic encapsulation layer 330 may include at least one inorganic material of aluminum oxide, titanium oxide, tantalum oxide, hafnium oxide, zinc oxide, silicon oxide, silicon nitride, and silicon oxynitride.

The first inorganic encapsulation layer 310 and the second inorganic encapsulation layer 330 may have a single layer or multi-layered structure. The first inorganic encapsulation layer 310 and the second inorganic encapsulation layer 330 may include a same material or different materials. A thickness of the first inorganic encapsulation layer 310 and a thickness of the second inorganic encapsulation layer 330 may be different from each other. The thickness of the first inorganic encapsulation layer 310 may be greater than the thickness of the second inorganic encapsulation layer 330. In another embodiment, a thickness of the second inorganic encapsulation layer 330 may be greater than the thickness of the first inorganic encapsulation layer 310, or the thicknesses of the first inorganic encapsulation layer 310 and the thickness of the second inorganic encapsulation layer 330 may be the same.

The organic encapsulation layer 320 may include a monomer-based material or a polymer-based material. The polymer-based material may include an acryl-based resin, an epoxy-based resin, polyimide, polyethylene, the like, or a combination thereof. In an embodiment, the organic encapsulation layer 320 may include acrylate or the like.

The barrier wall 200 may be disposed in the peripheral area PA of the substrate 100. In an embodiment, the barrier wall 200 may include a portion of the first organic insulating layer 104, a portion 230 of the second organic insulating layer 105, a portion 220 of the pixel-defining layer 106, and a portion 210 of the spacer 80. However, the disclosure is not limited thereto.

In embodiments, the barrier wall 200 may include only the portion 230 of the second organic insulating layer 105 or the portion 220 of the pixel-defining layer 106. The barrier wall 200 may surround the display area DA and may prevent the organic encapsulation layer 320 of the thin-film encapsulation layer TFE from overflowing to an outside of the substrate 100. The organic encapsulation layer 320 may contact a surface (e.g., an inner surface) of the barrier wall 200 toward the display area DA. In case that referring to the organic encapsulation layer 320 contacting the inner surface of the barrier wall 200, it may be understood that a first inorganic encapsulation layer 310 is disposed between the organic encapsulation layer 320 and the barrier wall 200, and the organic encapsulation layer 320 contacts the first inorganic encapsulation layer 310.

The first inorganic encapsulation layer 310 and the second inorganic encapsulation layer 330 may be disposed on the barrier wall 200 and may extend to edges of the substrate 100. However, in embodiments, multiple barrier walls 200 may be included in the display panel 10.

FIG. 4 is a schematic plan view illustrating sub-pixels of region A of FIG. 1.

For convenience of explanation, description will focus on sub-pixels disposed in region A, and description of other components will be omitted. FIG. 4 is a plan view, and unless otherwise noted, the description of FIG. 4 may be understood to be based on a plan view.

As illustrated in FIG. 4, a display apparatus according to an embodiment in a plan view may include multiple reference sub-pixels BX1 to BX6 and multiple sub-pixels SPX1 to SPX4. The display apparatus may include multiple reference sub-pixels and a first sub-pixel SPX1 and a second sub-pixel SPX2. The reference sub-pixels BX1 to BX6 may include a first reference sub-pixel BX1, a second reference sub-pixel BX2, an n-th reference sub-pixel, and the like. For convenience of explanation, a description will be provided on the basis of some reference sub-pixels.

The display apparatus may further include a third sub-pixel SPX3, a fourth sub-pixel SPX4, an n-th sub-pixel, and the like, as multiple sub-pixels. The first sub-pixel SPX1 to the fourth sub-pixel SPX4 may be arranged in a form of a diamond centered on the first reference sub-pixel BX1.

Multiple reference sub-pixels BX1 to BX6 may emit light in a first wavelength band, and may have a polygonal shape in a plan view. The reference sub-pixels BX1 to BX6 may include the first reference sub-pixel BX1, the second reference sub-pixel BX2, and the like, as described above.

The first reference sub-pixel BX1 may be a sub-pixel that emits light in a first wavelength band. For example, the first reference sub-pixel BX1 may be a sub-pixel that emits light in a wavelength band of green light. The first reference sub-pixel BX1 may have a polygonal shape including multiple lines in a plan view. For example, the polygonal shape of the first reference sub-pixel BX1 in a plan view may include at least one obtuse angle, and may be a polygonal shape including a line having a first length and a line having a second length. The first length may be greater than the second length.

As illustrated in FIG. 4, the first reference sub-pixel BX1 in a plan view may have a polygonal shape having a long axis and a short axis intersecting (e.g., intersecting approximately vertically) the long axis. In a plan view, the polygonal shape of the first reference sub-pixel BX1 may have a long axis and a short axis intersecting the long axis and may be a polygonal shape having at least one obtuse angle.

For example, the first reference sub-pixel BX1 may have an octagonal shape with a long axis and a short axis in a plan view. In the first reference sub-pixel BX1, multiple corners that constitute the octagonal shape may have obtuse angles. In FIG. 4, for convenience of explanation, a long axis Lx and a short axis Sx are indicated in a reference sub-pixel corresponding to the first reference sub-pixel BX1. However, a description of the long axis Lx and the short axis Sx may be similarly applied to other reference sub-pixels BX1 to BX6.

The first sub-pixel SPX1 may be a sub-pixel that emits light in a second wavelength band. For example, the first sub-pixel SPX1 may be a sub-pixel that emits light in a wavelength band of blue light. The first sub-pixel SPX1 may include multiple corners and lines each connecting the corner in a plan view. In the display apparatus according to an embodiment, the first sub-pixel SPX1 may be spaced apart from the first reference sub-pixel BX1 at equal intervals in a plan view. In a plan view, the first sub-pixel SPX1 may be uniformly spaced apart from the first reference sub-pixel BX1 by a distance (e.g., a certain or selectable distance) R.

The second sub-pixel SPX2 may be a sub-pixel that emits light in a third wavelength band. For example, the second sub-pixel SPX2 may be a sub-pixel that emits light having a wavelength band of red light. However, the disclosure is not limited thereto, and in embodiments, the third wavelength band and the first wavelength band or the second wavelength band may have substantially same or similar range.

The second sub-pixel SPX2 may include multiple corners and lines each connecting the corners in a plan view. In the display apparatus according to an embodiment, the second sub-pixel SPX2 may be spaced apart from the first reference sub-pixel BX1 at equal intervals in a plan view. In a plan view, the second sub-pixel SPX2 may be uniformly spaced apart from the first reference sub-pixel BX1 by a distance (e.g., a certain or selectable distance) R.

For organic light-emitting elements that emit light in the wavelength band of blue, a relatively short lifetime may be an issue, and in general, an area of the first sub-pixel SPX1 may be greater than an area of the second sub-pixel SPX2 in a plan view.

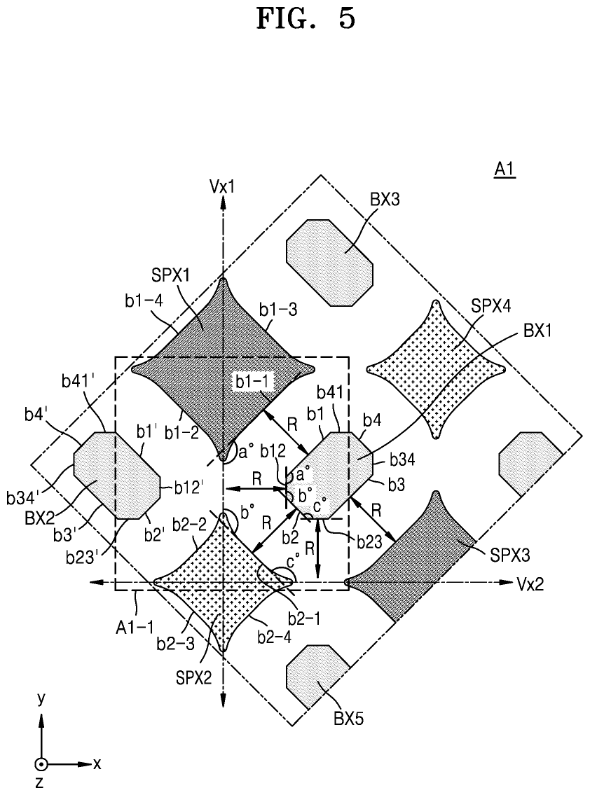

The display apparatus may further include a second reference sub-pixel BX2 that is symmetrical to the first reference sub-pixel BX1 based on a first virtual axis (see, e.g., Vx1 of FIG. 5). The first virtual axis will be described below. The second reference sub-pixel BX2 and the first reference sub-pixel BX1 may have same features, except that the second reference sub-pixel BX2 has a shape that is symmetrical to the first reference sub-pixel BX1 in a plan view.

The third sub-pixel SPX3 may be symmetrical to the first sub-pixel SPX1 based on the long axis of the first reference sub-pixel BX1. The third reference sub-pixel SPX3 and the first sub-pixel SPX1 may have same features, except that the third reference sub-pixel SPX3 has a shape that is symmetrical to the first sub-pixel SPX1 in a plan view.

The fourth sub-pixel SPX4 may be symmetrical to the second sub-pixel SPX2 based on the short axis of the first reference sub-pixel BX1. The fourth sub-pixel SPX4 and the second sub-pixel SPX2 may have same features, except that the fourth sub-pixel SPX4 has a shape that is symmetrical to the second sub-pixel SPX2 in a plan view.

The first reference sub-pixel BX1 may be spaced apart from the first sub-pixel SPX1 and the second sub-pixel SPX2 by a distance (e.g., a certain or selectable distance) R. Other sub-pixels SPX3 and SPX4 than the first sub-pixel SPX1 and the second sub-pixel SPX2 may be spaced apart from the first reference sub-pixel BX1 by a distance (e.g., a certain or selectable distance) R. For example, at least four sub-pixels SPX1 to SPX4 may be arranged around the first reference sub-pixel BX1 and spaced apart from the first reference sub-pixel BX1 by a distance (e.g., a certain or selectable distance) R. For example, at least four sub-pixels SPX1 to SPX4 may be arranged around the first reference sub-pixel BX1 at equal intervals.

FIG. 5 is a schematic plan view illustrating sub-pixels of region A1 of FIG. 4.

For convenience of explanation, descriptions will focus on sub-pixels disposed in region A1, and description of other components may be omitted. FIG. 5 is a plan view, and unless otherwise noted, the description of FIG. 5 may be understood to be based on a plan view.

As illustrated in FIG. 5, the polygonal shape of the first reference sub-pixel BX1 may include at least one obtuse angle, a (1-1)-th line segment b1, and a (1-2)-th line segment b2. The (1-1)-th line segment b1 may have a first length, the (1-2)-th line segment may have a second length, and the first length may be greater than or equal to the second length. The second length may be less than the first length. The (1-1)-th line segment b1 may be parallel to the long axis of the first reference sub-pixel BX1 in a plan view, and the (1-2)-th line segment b2 may be parallel to the short axis of the first reference sub-pixel BX1 in a plan view.

The polygonal shape of the first reference sub-pixel BX1 may include the (1-1)-th line segment b1, the (1-2)-th line segment b2, a (1-3)-th line segment b3, and a (1-4)-th line segment b4 in a plan view. The first reference sub-pixel BX1 may include a (1-1)-th line segment b12 connecting the (1-1)-th line segment b1 and the (1-2)-th line segment b2 to each other, a (1-2)-th line segment b23 connecting the (1-2)-th line segment b2 and the (1-3)-th line segment b3 to each other, a (1-3)-th line segment b34 connecting the (1-3)-th line segment b3 and the (1-4)-th line segment b4 to each other, and a (1-4)-th line segment b41 connecting the (1-4)-th line segment b4 and the (1-1)-th line segment b1 to each other.

However, the disclosure is not limited thereto, and according to a design, the first reference sub-pixel BX1 may include or omit at least one line segment, and may include or omit at least one line segment.

An extension of the (1-1)-th line segment b1 and an extension of the (1-2)-th line segment b2 may intersect (e.g., approximately vertically intersect) each other. The (1-1)-th line segment b1 and the (1-3)-th line segment b3 may be arranged parallel to each other in a plan view. The (1-2)-th line segment b2 and the (1-4)-th line segment b4 may be arranged parallel to each other in a plan view. An extension of the (1-3)-th line segment b3 and an extension of the (1-4)-th line segment b4 may also intersect (e.g., approximately vertically intersect) each other.

For example, the line segments (e.g., the (1-1)-th line segment b1, the (1-3)-th line segment b3) arranged parallel to the long axis in the first reference sub-pixel BX1 may have the first length described above, and the line segments (e.g., the (1-2)-th line segment b2, the (1-4)-th line segment b4) arranged parallel to the short axis may have the second length described above. The line segment with the first length and the line segment with the second length may be connected by line segments (e.g., the (1-1)-th line segment b12 to the (1-4)-th line segment b41) having a third length. The third length may be less than the first length. The third length and the second length may be same, or the third length may be less than the second length.

However, the disclosure is not limited thereto, and according to the design, the shape of the first reference sub-pixel BX1 may vary. The lengths of the (1-1)-th line segment b1 and the (1-3)-th line segment b3 may be different from each other, the lengths of the (1-2)-th line segment b2 and the (1-4)-th line segment b4 may be different from each other, and lengths of the line segment (e.g., the (1-1)-th line segment b12 and the (1-3)-th line segment b34, the (1-2)-th line segment b23 and the (1-4)-th line segment b41) may also be different from each other.

The second reference sub-pixel BX2 may be symmetrical to the first reference sub-pixel BX1, based on a first imaginary axis Vx1 extending in the y-axis direction. The first imaginary axis Vx1 may be an imaginary axis extending through a center of the first sub-pixel SPX1 and a center of the second sub-pixel SPX2. A second imaginary axis Vx2 may intersect the first imaginary axis Vx1. The second imaginary axis Vx2 may be an imaginary axis extending in the x-axis direction.

As illustrated in FIG. 5, the polygonal shape of the second reference sub-pixel BX2 may include at least one obtuse angle, a (2-1)-th line segment b1′, and a (2-2)-th line segment b2′. The (2-1)-th line segment b1′ may have a first′ length, the (2-2)-th line segment may have a second′ length, and the first′ length may be greater than or equal to the second′ length. The second′ length may be less than the first′ length. The (2-1)-th line segment b1′ may be parallel to the long axis of the second reference sub-pixel BX2 in a plan view, and the (2-2)-th line segment b2′ may be parallel to the short axis of the second reference sub-pixel BX2 in a plan view.

The polygonal shape of the second reference sub-pixel BX2 may include the (2-1)-th line segment b1′, the (2-2)-th line segment b2′, a (2-3)-th line segment b3′, and a (2-4)-th line segment b4′ in a plan view. The second reference sub-pixel BX2 may include a (2-1)-th line segment b12′ connecting the (2-1)-th line segment b1′ and the (2-2)-th line segment b2′ to each other, a (2-2)-th line segment b23′ connecting the (2-2)-th line segment b2′ and the (2-3)-th line segment b3′ to each other, a (2-3)-th line segment b34′ connecting the (2-3)-th line segment b3′ and the (2-4)-th line segment b4′ to each other, and a (2-4)-th line segment b41′ connecting the (2-4)-th line segment b4′ and the (2-1)-th line segment b1′ to each other.

However, according to a design, the second reference sub-pixel BX2 may include or omit at least one other line segment, and may include or omit at least one other line segment.

An extension of the (2-1)-th line segment b1′ and an extension of the (2-2)-th line segment b2′ may intersect (e.g., approximately vertically intersect) each other. The (2-1)-th line segment b1′ and the (2-3)-th line segment b3′ may be arranged parallel to each other in a plan view. The (2-2)-th line segment b2′ and the (2-4)-th line segment b4′ may be arranged parallel to each other in a plan view. An extension of the (2-3)-th line segment b3′ and an extension of the (2-4)-th line segment b4′ may also intersect (e.g., approximately vertically intersect) each other.

For example, the line segments (e.g., the (2-1)-th line segment b1′, the (2-3)-th line segment b3′) arranged parallel to the long axis in the second reference sub-pixel BX2 may have the first′ length described above, and the line segments (e.g., the (2-2)-th line segment b2′, the (2-4)-th line segment b4′) arranged parallel to the short axis may have the second′ length described above. The line segment with the first′ length and the line segment with the second′ length may be connected by line segments (e.g., the (2-1)-th line segment b12′ to the (2-4)-th line segment b41′) with a third′ length. A size of the third′ length may be less than a size of the first′ length. A size of the third′ length and a size of the second′ length may be the same, or the size of the third′ length may be less than the size of the second′ length.

However, according to the design, the shape of the second reference sub-pixel BX2 may vary. The lengths of the (2-1)-th line segment b1′ and the (2-3)-th line segment b3′ may be different from each other, and the lengths of the (2-2)-th line segment b2′ and the (2-4)-th line segment b4′ may be different from each other, and the lengths of the line segments (e.g., the (1-1)-th line segment b12′ and the (1-3)-th line segment b34′, the (1-2)-th line segment b23′ and the (1-4)-th line segment b41′) may also be different from each other.

As illustrated in FIG. 5, the first sub-pixel SPX1 may include a (1-1)-th line b1-1 corresponding to (or facing) the (1-1)-th line segment b1 of the first reference sub-pixel BX1. The first sub-pixel SPX1 may further include a (1-2)-th line b1-2, a (1-3)-th line b1-3, and a (1-4)-th line b1-4 corresponding to line segments extending in the long axis direction of another reference sub-pixel. For example, the (1-2)-th line b1-2 of the first sub-pixel SPX1 may correspond to (or face) the (2-1)-th line segment b1′ of the second reference sub-pixel BX2.

An extension of the (1-1)-th line b1-1 may each intersect (e.g., approximately vertically intersect) an extension of the (1-2)-th line b1-2 and an extension of the (1-3)-th line b1-3, and the (1-1)th line b1-1 may be arranged approximately parallel to the (1-4)-th line b1-4.

The second sub-pixel SPX2 may include a (2-1)-th line b2-1 corresponding to (or facing) the (1-2)-th line segment b2 of the first reference sub-pixel BX1. The second sub-pixel SPX2 may further include a (2-2)-th line b2-2, a (2-3)-th line b2-3, and a (2-4)-th line b2-4 corresponding to line segments extending in the short axis direction of another reference sub-pixel. For example, the (2-2)-th line b2-2 of the second reference sub-pixel SPX2 may correspond to (or face) the (2-2)-th line segment b2′ of the second reference sub-pixel BX2.

An extension of the (2-1)-th line b2-1 may each intersect (e.g., approximately vertically intersect) an extension of the (2-2)-th line b2-2 and an extension of the (2-3)-th line b2-3, and the (2-1)-th line b2-1 may be arranged approximately parallel to the (2-4)-th line b2-4.

A length of the (1-1)-th line segment b1 and a length of the (1-1)-th line segment b1-1 may be approximately the same. A length of the (1-1)-th line segment b1 and a length of the (1-4)-th line segment b1-4 may be approximately the same.

A third reference sub-pixel BX3 and the first reference sub-pixel BX1 may have a same specification, and the third reference sub-pixel BX3 may be disposed in the region A1. The third reference sub-pixel BX3 may be symmetrical to the first reference sub-pixel BX1, based on an imaginary axis (e.g., the second imaginary axis Vx2) passing through the center of the first sub-pixel SPX1 and extending in the x direction. A symmetry may also be applied to the fourth reference sub-pixel BX4, which is positioned to be symmetrical to the first reference sub-pixel BX1 around the first sub-pixel SPX1, or an imaginary axis passing through the center of the first sub-pixel SPX1 and extending between the x-axis direction and the y-axis direction.

In accordance with the symmetry described above, the length of the (1-1)-th line segment b1 and the length of the (1-2)-th line b1-2 may be approximately the same, and the length of the (1-1)-th line segment b1 and the length of the (1-3)-th line b1-3 may be approximately the same.

An equality or similarity of lengths may be because the (1-1)-th line segment b1-1 is defined to be tangent to an imaginary circle having as an origin each of points that constitute the (1-1)-th line segment b1 and having a distance (e.g., a certain or selectable distance) R as a radius. In an embodiment, the (1-1)-th line b1-1 may be tangent to all of the imaginary circles having a distance (e.g., a certain or selectable distance) R as a radius with each of the points including the (1-1)-th line segment b1 as an origin (or having a distance (e.g., a certain or selectable distance) R as a radius based on an origin on the (1-1)-th line segment b1. As a result, the (1-1)-th line b1-1 and the (1-1)-th line segment b1 may be always spaced apart from each other by a distance (e.g., a certain or selectable distance) R.

Similarly, the (1-2)-th line b1-2 may be defined by imaginary circles drawn based on the line segment (e.g., the (2-1)-th line segment b1′) of the second reference sub-pixel BX2 that is positioned closest to the (1-2)-th line b1-2. The (1-3)-th line b1-3 may be defined by imaginary circles drawn based on the line segment of the third reference sub-pixel BX3 that is positioned closest to the (1-3)-th line b1-3. The (1-4)-th line b1-4 may be defined by imaginary circles drawn based on the line segment of the fourth reference sub-pixel (see, e.g., BX4 of FIG. 4) that is positioned closest to the (1-4)-th line b1-4. The imaginary circles all have a radius equal to a distance (e.g., a certain or selectable distance) R, and the lines included in the first sub-pixel SPX1 may be uniformly spaced apart from all of neighboring reference sub-pixels BX1, BX2, BX3, and BX4 by a distance (e.g., a certain or selectable distance) R. For example, the lines included in the first sub-pixel SPX1 may be spaced apart from all of neighboring reference sub-pixels BX1, BX2, BX3, and BX4 at equal intervals.

A length of the (1-2)-th line segment b2 and a length of the (2-1)-th line segment b2-1 may be approximately the same. A length of the (1-2)-th line segment b2 and a length of the (2-4)-th line segment b2-4 may be approximately the same.

A fifth reference sub-pixel BX5 and the second reference sub-pixel BX2 may have a same specification, and the fifth reference sub-pixel BX5 may be disposed in the region A1. The fifth reference sub-pixel BX5 may be symmetrical to the second reference sub-pixel BX2, based on the second sub-pixel SPX2. A symmetry may also be applied to the sixth reference sub-pixel BX6, which is positioned to be symmetrical to the first reference sub-pixel BX1, based on the second sub-pixel SPX2.

In accordance with the symmetry described above, the length of the (1-2)-th line segment b2 and the length of the (2-2)-th line b2-2 may be approximately the same, and the length of the (1-2)-th line segment b2 and the length of the (2-3)-th line b2-3 may be approximately the same.

An equality or similarity of lengths may be because the (2-1)-th line segment b1′ is defined to be tangent to an imaginary circle having a radius of a distance (e.g., a certain or selectable distance) R from an origin of each of points including the (1-2)-th line segment b2 (or having a radius of a distance (e.g., a certain or selectable distance R from the origin on the (1-2)-th line segment b2). In an embodiment, the (2-1)-th line b2-1 may be tangent to all of the imaginary circles having an origin at each of the points including the (1-2)-th line segment b2 and having a radius of a distance (e.g., a certain or selectable distance) R. As a result, the (2-1)-th line b2-1 and the (1-2)-th line segment b2 may be always spaced apart from each other by a distance (e.g., a certain or selectable distance) R.

Similarly, the (2-2)-th line b2-2 may be defined by imaginary circles drawn based on the line segment (e.g., the (2-2)-th line segment b2′) of the second reference sub-pixel BX2 that is positioned closest to the (2-2)-th line b2-2. The (2-3)-th line b2-3 may be defined by imaginary circles drawn based on the line segment of a six reference sub-pixel (see, e.g., BX6 of FIG. 4) that is positioned closest to the (2-3)-th line b2-3. The (2-4)-th line b2-4 may be defined by imaginary circles drawn based on the line segment of the fifth reference sub-pixel BX5 that is positioned closest to the (2-4)-th line b2-4. The imaginary circles all have a radius equal to a distance (e.g., a certain or selectable distance) R, and the lines included in the second sub-pixel SPX2 may be uniformly spaced from all of neighboring reference sub-pixels BX1, BX2, BX5, and BX6 by a distance (e.g., a certain or selectable distance) R. For example, the lines included in the second sub-pixel SPX2 may be spaced apart from all of neighboring reference sub-pixels BX1, BX2, BX5, and BX6 at equal intervals.

A (1-1)-th angle a° Formed by an intersection of the (1-1)-th line segment b1 and the (1-1)-th line segment b12 of the first reference sub-pixel BX1 may be an obtuse angle. The (1-1)-th angle a° may be the smaller of two angles formed by the intersection of the (1-1)-th line segment b1 and the (1-1)-th line segment b12 (e.g., a sum of the two angles is about 360)°.

A (1-2)-th angle b° Formed by an intersection of the (1-2)-th line segment b2 and the (1-1)-th line segment b12 of the first reference sub-pixel BX1 may be an obtuse angle. The (1-2)-th angle b° may be the smaller of two angles formed by the intersection of the (1-2)-th line segment b2 and the (1-1)-th line segment b12 (e.g., a sum of the two angles is about 360)°.

A (1-3)-th angle c° Formed by an intersection of the (1-2)-th line segment b2 and the (1-2)-th line segment b23 of the first reference sub-pixel BX1 may be an obtuse angle. The (1-3)-th angle c° may be the smaller of two angles formed by the intersection of the (1-2)-th line segment b2 and the (1-2)-th line segment b23 (e.g., the sum of the two angles is about 360)°.

The first reference sub-pixel BX1 may have other angles (e.g., in case that the first reference sub-pixel BX1 is an octagon, it may have other angles such as a (1-4)-th angle to a (1-8)-th angle, and the like), and for convenience of explanation, contents of the (1-4)-th angle to the (1-8)-th angle, and the like may be replaced by the contents described above.

As illustrated in FIG. 5, an angle formed by an intersection of an extension of the (1-1)-th line b1-1 and the first imaginary axis Vx1 may be approximately equal to the (1-1)-th angle a°. This is because the (1-1)-th line segment b12 and the first imaginary axis Vx1 are arranged approximately parallel to each other.

An angle formed by an intersection of an extension of the (2-1)-th line b2-1 and the first imaginary axis Vx1 may be approximately equal to the (1-2)-th angle b°. This is also because the (1-1)-th line segment b12 and the first imaginary axis Vx1 are arranged approximately parallel to each other.

An angle formed by an intersection of an extension of the (2-1)-th line b2-1 and the second imaginary axis Vx2 may be approximately equal to the (1-3)-th angle c°. This is because the (1-2)-th line segment b23 and the second imaginary axis Vx2 are arranged approximately parallel to each other. The second imaginary axis Vx2 that is an imaginary axis extending in the x-axis direction may intersect (e.g., approximately vertically intersect) the first imaginary axis Vx1.

Each of other angles of the first reference sub-pixel BX1 may also be equal to each of other angles between line segments of other neighboring sub-pixels SPX1, SPX2, SPX3, or SPX4 and the imaginary axis Vx1 and/or Vx2, which will be omitted for convenience of explanation.

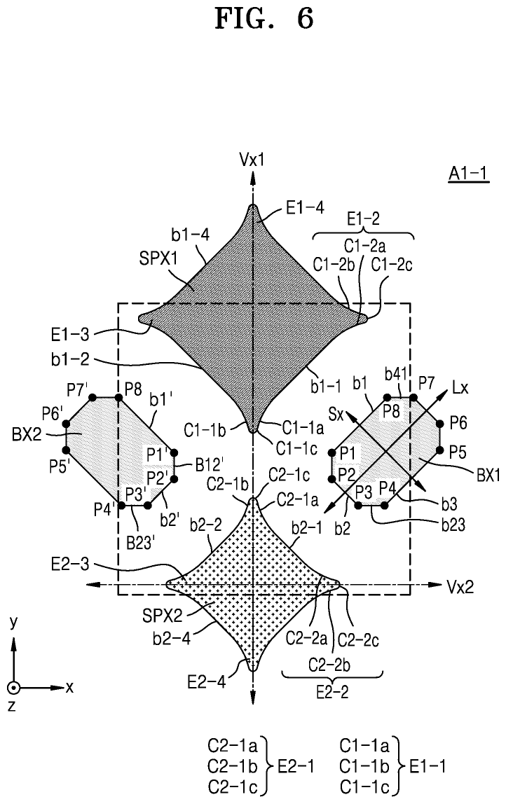

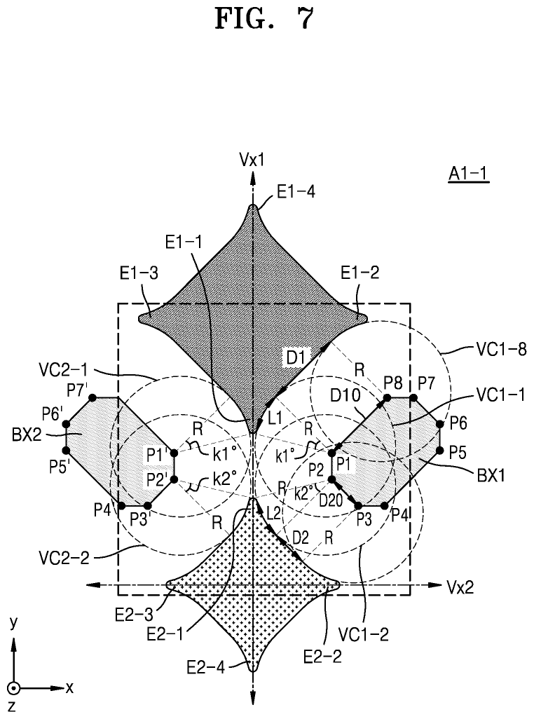

FIGS. 6 and 7 are schematic plan views illustrating sub-pixels arranged in region A1-1 of FIG. 5.

For convenience of explanation, descriptions will focus on sub-pixels disposed in region A1-1, and description of other components may be omitted. FIGS. 6 and 7 are plan views, and unless otherwise noted, the description of FIGS. 6 and 7 may be understood to be based on a plan view.

As illustrated in FIGS. 6 and 7, the first reference sub-pixel BX1 may have multiple vertexes P1 to P8. For example, in case that the first reference sub-pixel BX1 is a polygon, the number of vertexes may be equal to the number of corners of the polygon in the first reference sub-pixel BX1. For example, the first reference sub-pixel BX1, which has an octagonal shape in a plan view, may include a (1-1)-th vertex P1 to a (1-8)-th vertex P8.

For example, the second reference sub-pixel BX2, which has an octagonal shape in a plan view, may be symmetrical to the first reference sub-pixel BX1 based on the first imaginary axis Vx1, and the second reference sub-pixel BX2 may also include a (2-1)-th vertex P1′ to a (2-8)-th vertex P8′ that are symmetrical to the (1-1)-th vertex P1 and the (1-8)-th vertex P8, respectively.

In an embodiment, the first sub-pixel SPX1 may include a (1-1)-th corner E1-1, a (1-2)-th corner E1-2, a (1-3)-th corner E1-3, and a (1-4)-th corner E1-4. The (1-1)-th corner E1-1 and the (1-2)-th corner E1-2 may be connected to each other by the (1-1)-th line b1-1, and the (1-1)-th corner E1-1 and the (1-3)-th corner E1-3 may be connected to each other by the (1-2)-th line b1-2, the (1-2)-th corner E1-2 and the (1-4)-th corner E1-4 may be connected to each other by the (1-3)-th line b1-3, and the (1-3)-th corner E1-3 and the (1-4)-th corner E1-4 may be connected to each other by the (1-4)-th line b1-4.

In an embodiment, a shape of the first sub-pixel SPX1 may include a (1-1)-th line b1-1 corresponding to the (1-1)-th line segment b1, and a (1-1)-th corner E1-1 connected to the (1-1)-th line b1-1 and protruding toward the second sub-pixel SPX2 in the first imaginary axis Vx1 in a plan view. For example, a length D1 of the a (1-1)-th line b1-1 may correspond a length D10 of the (1-1)-th line segment b1.

In an embodiment, the (1-1)-th line b1-1 may be tangent to an imaginary circle having a radius of a distance (e.g., a certain or selectable distance) R based (or centered) on an origin on the (1-1)-th line segment b1 among the imaginary circles having a radius of a distance (e.g., a certain or selectable distance) R based on an origin on a side of the reference sub-pixels BX1 and BX2.

As described above, the first sub-pixel SPX1 may be spaced apart from the first reference sub-pixel BX1 by a distance (e.g., a certain or selectable distance) R. In a plan view, a (1-1)-th corner E1-1 to a (1-4)-th corner E1-4 may include a curve that curves approximately inwardly.

For example, the (1-1)-th corner E1-1 may include a (1-1a)-th curve C1-1a and a (1-1b)-th curve C1-1b that is approximately symmetrical to the (1-1a)-th curve C1-1a based on the first imaginary axis Vx1. For example, the (1-1)-th corner E1-1 may be defined by the (1-1a)-th curve C1-1a that curves approximately inwardly, the (1-1b)-th curve C1-1b, and a (1-1c)-th curve C1-1c that connects the (1-1a)-th curve C1-1a and the (1-1b)-th curve C1-1b and protrudes toward the second sub-pixel SPX2.

The (1-1a)-th curve C1-1a may have a (1-1)-th vertex P1 of the first reference sub-pixel BX1 as an origin and may extend in a (1-1)-th imaginary circle VC1-1 having a distance (e.g., a certain or selectable distance) R as a radius. The (1-1a)-th curve C1-1a may be a curve bent in a circumference of the (1-1)-th imaginary circle VC1-1.

For example, a length of the (1-1a)-th curve C1-1a may have the (1-1)-th vertex P1 of the first reference sub-pixel BX1 as an origin and may be approximately equal to a length of a (1-1)-th arc L1 of a fan shape defined by a (1-1)-th arc degree of the circumference of the (1-1)-th imaginary circle VC1-1 having the distance R as a radius.

For example, the (1-1a)-th curve C1-1a may be a fan-shaped (1-1)-th arc L1 rotated by a (1-1)-th arc degree k1° from an imaginary base line extending perpendicular to the (1-1)-th line segment b1 in the (1-1)-th vertex P1 in the circumference of the (1-1)-th imaginary circle VC1-1 having the (1-1)-th vertex P1 as the origin and a distance (e.g., a certain or selectable distance) R as the radius.

In an embodiment, the (1-1)-th corner E1-1 may be partially defined by the (1-1a)-th curve C1-1a, which bends in a curvature of the circumference of the imaginary circle. The imaginary circle maybe an imaginary circle having a radius of a distance (e.g., a certain or selectable distance) R based (or centered) on the (1-1)-th vertex P1 of the first reference sub-pixel BX1 among the imaginary circles having a radius of a distance (e.g., a certain or selectable distance) R based on an origin on the side of the reference sub-pixels BX1 and BX2. The (1-1)-th vertex P1 may be a vertex closest to the (1-1)-th corner E1-1 among vertexes that constitute the polygonal shape of the first reference sub-pixel BX1 in a plan view.

The (1-1b)-th curve C1-1b may have a (2-1)-th vertex P1′ of the second reference sub-pixel BX2 as an origin and may extend in a (2-1)-th imaginary circle VC2-1 having a distance (e.g., a certain or selectable distance) R as a radius. The (1-1b)-th curve C1-1b may be a curve bent in a circumference of the (2-1)-th imaginary circle VC2-1.

For example, a length of the (1-1b)-th curve C1-1b may have the (2-1)-th vertex P1′ of the second reference sub-pixel BX2 as an origin and may be approximately equal to a length of a (2-1)-th arc L2 of a fan shape defined by a (2-1)-th arc degree of the circumference of the (2-1)-th imaginary circle VC2-1 having the distance R as a radius.

For example, the (1-1b)-th curve C1-1b may be a fan-shaped (2-1)-th arc rotated by a (2-1)-th arc degree from an imaginary base line extending perpendicular to the (2-1)-th line segment b1′ in the (2-1)-th vertex P1′ in the circumference of the (2-1)-th imaginary circle VC2-1 having the (2-1)-th vertex P1′ as the origin and a distance (e.g., a certain or selectable distance) R as the radius. The (2-1)-th arc degree and the (1-1)-th arc degree may be approximately the same angle k1°.

In an embodiment, the (1-1)-th corner E1-1 may be partially defined by the (1-1b)-th curve C1-1b, which bends in the curvature of the circumference of the imaginary circle. The imaginary circle may be an imaginary circle having a radius of a distance (e.g., a certain or selectable distance) R based on the (2-1)-th vertex P1′ of the second reference sub-pixel BX2 among the imaginary circles having a radius of a distance (e.g., a certain or selectable distance) R based on an origin on the side of the reference sub-pixels BX1 and BX2. The (2-1)-th vertex P1′ may be the vertex closest to the (1-1)-th corner E1-1 among the vertexes that constitutes the polygonal shape of the second reference sub-pixel BX2 in a plan view.

The (1-1c)-th curve C1-1c that is a curve connecting the (1-1a)-th curve C1-1a and the (1-1b)-th curve C1-1b to each other may be a convex line protruding from the center of the first sub-pixel SPX1 toward the center of the second sub-pixel SPX2. In another embodiment, the (1-1c)-th curve C1-1c that is a curve connecting the (1-1a)-th curve C1-1a and the (1-1b)-th curve C1-1b to each other may be a convex line protruding from the center of the first sub-pixel SPX1 in a −y-axis direction.

The (1-1c)-th curves C1-1c may be varied by a distance between the first reference sub-pixel BX1 and the second reference sub-pixel BX2 (e.g., a distance between the closest vertexes, or the like), and a distance between the first sub-pixel SPX1 and the second sub-pixel SPX2 (e.g., a distance between the center points or reference points of each sub-pixel, or the like).

Similarly, the first sub-pixel SPX1 may further include a (1-2)-th corner E1-2 including a (1-2a)-th curve C1-2a, a (1-2b)-th curve C1-2b, and a (1-2c)-th curve C1-2c that connects the (1-2a)-th curve C1-2a and the (1-2a)-th curve C1-2b to each other. Features of each of the curves C1-2a, C1-2b, and C1-2c including the (1-2)-th corner E1-2 and features of each of the curves C1-1a, C1-1b, and C1-1c including the (1-1)-th corner E1-1 that is symmetrical to the (1-2)-th corner E1-2 based on the (1-1)-th line b1-1 may be the substantially same or similar. However, the disclosure is not limited thereto, and the vertex of the imaginary circle for defining the (1-2a)-th curve C1-2a may be the (1-8)-th vertex P8, and the vertex of the imaginary circle for defining the (1-2b)-th curve C1-2b may be the vertex of the vertex of the third reference sub-pixel BX3 in FIG. 5 that is located closest to the (1-2b)-th curve C1-2b. Furthermore, criterion for defining the (1-2c)-th curve C1-2c may be a convex line protruding in the x-axis direction from the center of the first sub-pixel SPX1.

Some of the curves including the corners E1-1 to E1-4 included in the first sub-pixel SPX1 may be defined by imaginary circles according to the adjacent reference sub-pixels BX1 and BX2, and the other of the curves including the edges included in the first sub-pixel SPX1 may be defined by lines convex in a direction (e.g., a particular direction) from the center of the first sub-pixel SPX1. The corners E1-1 to E1-4 included in the first sub-pixel SPX1 may have approximately symmetry with respect to the center of the first sub-pixel SPX1, and the overall features may be self-evident to those skilled in the art from the above description and the drawings alone.

As described above, the second sub-pixel SPX2 may be spaced apart from the first reference sub-pixel BX1 by a distance (e.g., a certain or selectable distance) R. In a plan view, a (2-1)-th corner E2-1 to a (2-4)-th corner E2-4 may include a curve that curves approximately inwardly.

In an embodiment, the second sub-pixel SPX2 may include a (2-1)-th corner E2-1, a (2-2)-th corner E2-2, a (2-3)-th corner E2-3, and a (2-4)-th corner E2-4. The (2-1)-th corner E2-1 and the (2-2)-th corner E2-2 may be connected to each other by the (2-1)-th line b2-1, and the (2-1)-th corner E2-1 and the (2-3)-th corner E2-3 may be connected to each other by the (2-2)-th line b2-2, the (2-2)-th corner E2-2 and the (2-4)-th corner E2-4 may be connected to each other by the (2-3)-th line b2-3, and the (2-3)-th corner E2-3 and the (2-4)-th corner E2-4 may be connected to each other by the (2-4)-th line b2-4.

In an embodiment, a shape of the second sub-pixel SPX2 may include a (2-1)-th line b2-1 corresponding to the (1-2)-th line segment b2, and a (2-1)-th corner E2-1 connected to the (2-1)-th line b2-1 and protruding toward the first sub-pixel SPX1 in the first imaginary axis Vx1 in a plan view. For example, a length D2 of the a (2-1)-th line b2-1 may correspond a length D20 of the (1-2)-th line segment b2.

In an embodiment, the (2-1)-th line b2-1 may be tangent to all of the imaginary circles having an origin at each of the points including the (1-2)-th line segment b2 and having a radius of a distance (e.g., a certain or selectable distance) R. The imaginary circles may be different portions of imaginary circles having a radius of a distance (e.g., a certain or selectable distance) R based on an origin on the side of the reference sub-pixels BX1 and BX2.

For example, the (2-1)-th corner E2-1 may include a (2-1a)-th curve C2-1a and a (2-1b)-th curve C2-1b that is approximately symmetrical to the (2-1a)-th curve C2-1a based on the first imaginary axis Vx1. For example, the (2-1)-th corner E2-1 may be defined by the (2-1a)-th curve C2-1a that curves approximately inwardly, the (2-1b)-th curve C2-1b, and a (2-1c)-th curve C2-1c that connects the (2-1a)-th curve C2-1a and the (2-1b)-th curve C2-1b and protrudes toward the first sub-pixel SPX1.

The (2-1a)-th curve C2-1a may have a (1-2)-th vertex P2 of the first reference sub-pixel BX1 as an origin and may extend in a (1-2)-th imaginary circle VC1-2 having a distance (e.g., a certain or selectable distance) R as a radius. The (2-1a)-th curve C2-1a may have a (1-2)-th vertex P2 of the first reference sub-pixel BX1 as an origin and may be a curve bent in a circumference of the (1-2)-th imaginary circle VC1-2 having a distance (e.g., a certain or selectable distance) R as a radius.

In an embodiment, the (2-1)-th corner E2-1 may be partially defined by the (2-1a)-th curve C2-1a, which bends in the curvature of the circumference of the imaginary circle. The imaginary circle may be an imaginary circle having a radius of a distance (e.g., a certain or selectable distance) R based on the (1-2)-th vertex P2 of the first reference sub-pixel BX1 among the imaginary circles having a radius of a distance (e.g., a certain or selectable distance) R based on an origin on the side of the reference sub-pixels BX1 and BX2. The (1-2)-th vertex P2 may be a vertex closest to the (2-1)-th corner E2-1 among the vertexes that constitute the polygonal shape of the first reference sub-pixel BX1 in a plan view.

For example, a length of the (2-1a)-th curve C2-1a may have the (1-2)-th vertex P2 of the first reference sub-pixel BX1 as an origin and may be approximately equal to a length of a (1-2)-th arc L1 of a fan shape defined by a (1-2)-th arc degree of the circumference of the (1-2)-th imaginary circle VC1-2 having the distance R as a radius.

For example, the (2-1a)-th curve C2-1a may be a fan-shaped (1-2)-th arc L2 rotated by a (1-2)-th arc degree from an imaginary base line extending perpendicular to the (1-2)-th line segment b2 in the (1-2)-th vertex P2 in the circumference of the (1-2)-th imaginary circle VC1-2 having the (1-2)-th vertex P2 as the origin and a distance (e.g., a certain or selectable distance) R as the radius.

The (2-1b)-th curve C2-1b may have a (2-2)-th vertex P2′ of the second reference sub-pixel BX2 as an origin and may extend in a (2-2)-th imaginary circle VC2-2 having a distance (e.g., a certain or selectable distance) R as a radius. The (2-1b)-th curve C2-1b may have a (2-2)-th vertex P2′ of the second reference sub-pixel BX2 as an origin and may be a curve bent in the circumference of the (2-2)-th imaginary circle VC2-2 having a distance (e.g., a certain or selectable distance) R as a radius.

For example, the length of the (2-1b)-th curve C2-1b may have the (2-2)-th vertex P2′ of the second reference sub-pixel BX2 as an origin and may be approximately equal to the length of the (2-2)-th arc of a fan shape defined by the (2-2)-th arc degree of the circumference of the (2-2)-th imaginary circle VC2-2 having the distance R as a radius.

For example, the (2-1b)-th curve C2-1b may be a fan-shaped (2-2)-th arc rotated by a (2-2)-th arc degree from an imaginary base line extending perpendicular to the (2-2)-th line segment b1′ in the (2-2)-th vertex P2′ in the circumference of the (2-2)-th imaginary circle VC2-2 having the (2-2)-th vertex P2′ as the origin and a distance (e.g., a certain or selectable distance) R as the radius. The (2-2)-th arc degree may be approximately the same angle k2° as the (1-2)-th arc degree.

In an embodiment, the (2-1)-th corner E2-1 may be partially defined by the (2-1b)-th curve C2-1b, which bends in the curvature of the circumference of the imaginary circle. The imaginary circle may refer to an imaginary circle having a radius of a distance (e.g., a certain or selectable distance) R based on the (2-2)-th vertex P2′ of the second reference sub-pixel BX2 among the imaginary circles having a radius of a distance (e.g., a certain or selectable distance) R based on an origin on the side of the reference sub-pixels. The (2-2)-th vertex P2′ may be a vertex closest to the (2-1)-th corner E2-1 among the vertexes that constitute the polygonal shape of the second reference sub-pixel BX2 in a plan view.

The (2-1c)-th curve C2-1c that is a curve connecting the (2-1a)-th curve C2-1a and the (2-1b)-th curve C2-1b to each other may be a convex line protruding from the center of the first sub-pixel SPX1 toward the center of the second sub-pixel SPX2. In another embodiment, the (2-1c)-th curve C2-1c that is a curve connecting the (2-1a)-th curve C2-1a and the (2-1b)-th curve C2-1b to each other may be a convex line protruding from the center of the second sub-pixel SPX2 in a +y-axis direction.

The (2-1c)-th curves C2-1c may be varied by a distance between the first reference sub-pixel BX1 and the second reference sub-pixel BX2 (e.g., a distance between the closest vertexes, or the like), and a distance between the first sub-pixel SPX1 and the second sub-pixel SPX2 (e.g., a distance between the center points or reference points of each sub-pixel, or the like).

Similarly, the second sub-pixel SPX2 may further include a (2-2)-th corner E2-2 including a (2-2a)-th curve C2-2a, a (2-2b)-th curve C2-2b, and a (2-2c)-th curve C2-2c that connects the (2-2a)-th curve C2-2a and the (2-2b)-th curve C2-2b to each other. Features of each of the curves C2-2a, C2-2b, and C2-3b including the (2-2)-th corner E2-2 and features of each of the curves C2-1a, C2-1b, and C2-1c including the (2-1)-th corner E2-1 that is symmetrical to the (2-2)-th corner E2-2 based on the (2-1)-th line segment b1′ may be the substantially same or similar. However, the disclosure is not limited thereto, the vertex of the imaginary circle for defining the (2-2a)-th curve C2-2a may be the (1-3)-th vertex P3, and the vertex of the imaginary circle for defining the (2-2b)-th curve C2-2b may be the vertex that is located closest to the (2-2b)-th curve C2-2b among vertexes of other reference sub-pixels (not shown) symmetrical to the second reference sub-pixel BX2 based on the second sub-pixel SPX2. Furthermore, criterion for defining the (2-2c)-th curve C2-2c may be a convex line protruding in the +x-axis direction from the center of the second sub-pixel SPX2.

Some of the curves including the corners E2-1 to E2-4 included in the second sub-pixel SPX2 may be defined by imaginary circles according to the adjacent reference sub-pixels BX1 and BX2, and the other of the curves including the edges included in the second sub-pixel SPX2 may be defined by lines convex in a direction (e.g., a particular direction) from the center of the second sub-pixel SPX2. The corners E2-1 to E2-4 included in the second sub-pixel SPX2 may have approximately symmetry with respect to the center of the second sub-pixel SPX2, and the overall features may be self-evident to those skilled in the art from the above description and the drawings alone.

Furthermore, criteria for defining the corners E1-1 to E1-4 included in the first sub-pixel SPX1 may define the edges included in other sub-pixels that are symmetrical to the first sub-pixel SPX1, or the other sub-pixels and the first sub-pixel SPX1 have approximately a same shape in a plan view, and such applications may be self-evident to those skilled in the art from the above description and the drawings of this specification alone.

Furthermore, criteria for defining the corners E2-1 to E2-4 included in the second sub-pixel SPX2 may define the corners included in other sub-pixels that are symmetrical to the second sub-pixel SPX2, or the other sub-pixels and the second sub-pixel SPX2 may have approximately a same shape in a plan view, and such applications may be self-evident to those skilled in the art from the above description and the drawings of this specification alone.

As shown in FIGS. 6 and 7, an overall shape of the (1-1a)-th curve C1-1a of the (1-1)-th corner E1-1, the (1-2a)-th curve C1-2a of the (1-2)-th corner E1-2, and the (1-1)-th line b1-1 connecting the (1-1a)-th curve C1-1a and the (1-2a)-th curve C1-2a to each other may correspond to a partial shape of the first reference sub-pixel BX1. The overall shape of the (1-1a)-th curve C1-1a of the (1-1)-th corner E1-1, the (1-2a)-th curve C1-2a of the (1-2)-th corner E1-2, and the (1-1)-th line b1-1 connecting the (1-1a)-th curve C1-1a and the (1-2a)-th curve C1-2a to each other may correspond to a shape of the (1-1)-th line segment b1 of the first reference sub-pixel BX1, a portion of the circumference of the (1-1)-th imaginary circle VC1-1 having a radius of a distance (e.g., a certain or selectable distance) R based on the (1-1)-th vertex P1, and a portion of the circumference of the (1-8)-th imaginary circle VC1-8 having a radius of a distance (e.g., a certain or selectable distance) R based on the (1-8)-th vertex P8.

In summary, a shape of the (1-1)-th line b1-1 connecting a portion (e.g., the (1-1a)-th curve C1-1a) of the (1-1)-th corner E1-1 and a portion (e.g., the (1-2a)-th curve C1-2a) of the (1-2)-th corner E1-2 may be defined by the (1-1)-th line segment b1 of the first reference sub-pixel BX1, a portion of the circumference of the (1-1)-th imaginary circle VC1-1 having a radius of a distance (e.g., a certain or selectable distance) R based on the (1-1)-th vertex P1, and a portion of the circumference of the (1-8)-th imaginary circle VC1-1 having a radius of a distance (e.g., a certain or selectable distance) R based on the (1-8)-th vertex P8. The (1-1)-th vertex P1 and the (1-8)-th vertex P8 may be two end points of the (1-1)-th line b1-1.

A display apparatus according to an embodiment may include a first reference sub-pixel BX1, a second reference sub-pixel BX2, a first sub-pixel SPX1, and a second sub-pixel SPX2. Some of the (1-1)-th corner E1-1 of the first sub-pixel SPX1 may be curves defined by an imaginary circle having a radius of a distance (e.g., a certain or selectable distance) R based on a vertex of the first reference sub-pixel BX1, and an imaginary circle having a radius of a distance (e.g., a certain or selectable distance) R based on a vertex of the second reference sub-pixel BX2. The other of the (1-1)-th corner E1-1 of the first sub-pixel SPX1 may be a convex (or protruding) curve in an outward direction of the first sub-pixel SPX1, connecting the curves defined by the imaginary circles described above.

A portion of a side of the first sub-pixel SPX1 disposed around the first reference sub-pixel BX1 may be spaced apart from the first reference sub-pixel BX1 at equal intervals. The first sub-pixel SPX1 may be spaced apart from the first reference sub-pixel BX1 at equal intervals. The first sub-pixel SPX1 may be uniformly spaced apart from the first reference sub-pixel BX1 by a distance (e.g., a certain or selectable distance) R.

A “distance R” in this specification is a certain, predetermined, or selectable distance, which may change according to the design or resolution or the like. As used herein, a “distance R” is a preset distance, which may mean a same distance.

The sub-pixels in this specification may have a shape defined by a combination of lines and curves in a plan view. The lines and curves of sub-pixels may be defined by an imaginary circle having a radius of a distance (e.g., a certain or selectable distance) R based on the points that constitute the sides of adjacent reference sub-pixels.

As in the disclosure, sub-pixels (see, e.g., the first to fourth sub-pixels SPX1 to SPX4) spaced apart from a centrally disposed reference sub-pixel (see, e.g., the first reference sub-pixel BX1 of FIG. 4) at equal intervals may have a beneficial effect on obtaining an aperture rate. In case that the sub-pixel and reference sub-pixel are not spaced apart from each other at equal intervals, it may adversely affect uniform light emission through a light-emitting element.

Furthermore, the curves including the corners included in the sub-pixels are spaced apart from the vertexes of the reference sub-pixel at equal intervals, the disclosure may have the advantage of obtaining apertures as described above.

The pixel-defining layer (see, e.g., 106 of FIG. 3) may be disposed between sub-pixels and a reference sub-pixel. The pixel-defining layer may have a pixel-defining layer gap (hereinafter, PDL gap), and the corners of the sub-pixels may extend beyond the PDL gap required to maintain equal spacing, the light emitting area of the sub-pixels may be maximized. For example, the disclosure may have an effect of utilizing a space between sub-pixels as efficiently as possible according to a design of the corners included in each sub-pixel. Furthermore, as a variety of pixel designs is expanded by recently developed microprocesses, it may be important to have a pixel design such as the disclosure that utilizes the microprocesses and make the most efficient use of the space between sub-pixels.

Maintaining equal spacing between sub-pixels may be very important for this reason. In case that a sub-pixel is set as a reference in a pixel design (e.g., the first reference sub-pixel) and an imaginary circle with a same radius passing over the side of the reference sub-pixel is utilized, it is possible to maintain equal spacing between sub-pixels.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a first reference sub-pixel emitting light in a first wavelength band and having a polygonal shape in a plan view;
a first sub-pixel emitting light in a second wavelength band and having a first shape in a plan view defined by a portion of imaginary circles each having a radius and a center disposed on a side of the polygonal shape; and
a second sub-pixel emitting light in a third wavelength band and having a second shape in a plan view defined by another portion of the imaginary circles.

2. The display apparatus of claim 1, wherein the first reference sub-pixel is spaced apart from the first sub-pixel and the second sub-pixel by the radius.

3. The display apparatus of claim 2, wherein the polygonal shape of the first reference sub-pixel comprises:
at least one obtuse angle;
a first-first line segment having a first length; and
a first-second line segment having a second length that is less than the first length.

4. The display apparatus of claim 3, wherein
a center of the first sub-pixel and a center of the second sub-pixel are arranged on a first imaginary axis, and
the first shape of the first sub-pixel comprises:
a first-first line corresponding to the first-first line segment; and
a first-first corner connected to the first-first line and protruding toward the second sub-pixel along the first imaginary axis.

5. The display apparatus of claim 4, wherein the first-first line contacts one of the imaginary circles having a center disposed on the first-first line segment.

6. The display apparatus of claim 4, wherein the first-first corner is partially defined by a first-first curve, which is bent along a curvature of a circumference of one of the imaginary circles having a center disposed on a first-first vertex of the first reference sub-pixel.

7. The display apparatus of claim 6, wherein the first-first vertex is disposed closest to the first-first corner among vertexes of the polygonal shape of the first reference sub-pixel in a plan view.

8. The display apparatus of claim 6, further comprising:
a second reference sub-pixel having the polygonal shape in a plan view, spaced apart from the first sub-pixel and the second sub-pixel by the radius, and being symmetrical to the first reference sub-pixel based on the first imaginary axis.

9. The display apparatus of claim 8, wherein the first-first corner is partially defined by a first-second curve, which is bent along a curvature of a circumference of one of the imaginary circles having a center disposed on a second-first vertex of the second reference sub-pixel.

10. The display apparatus of claim 9, wherein the second-first vertex is disposed closest to the first-first corner among vertexes of the polygonal shape of the second reference sub-pixel in a plan view.

11. The display apparatus of claim 9, wherein the first-first corner comprises:
the first-first curve;
the first-second curve; and
a first-third curve connecting the first-first curve and the first-second curve to each other and being convex.

12. The display apparatus of claim 1, wherein the polygonal shape comprises a long axis and a short axis intersecting the long axis in a plan view.

13. The display apparatus of claim 12, wherein the polygonal shape is an octagonal shape.

14. The display apparatus of claim 3, wherein
a center of the first sub-pixel and a center of the second sub-pixel are arranged on a first imaginary axis, and
the second shape of the second sub-pixel comprises:
a second-first line corresponding to the first-second line segment; and
a second-first corner connected to the second-first line and protruding toward the first sub-pixel along the first imaginary axis.

15. The display apparatus of claim 14, wherein the second-first line contacts one of the imaginary circles having a center disposed on the (1-2)-th line segment.

16. The display apparatus of claim 14, wherein the second-first corner is partially defined by a second-first curve, which is bent along a curvature of a circumference of one of the imaginary circles having a center disposed on a (1-2)-th vertex of the first reference sub-pixel.

17. The display apparatus of claim 16, wherein the (1-2)-th vertex is disposed closest to the second-first corner among vertexes of the polygonal shape of the first reference sub-pixel in a plan view.

18. The display apparatus of claim 16, further comprising:
a second reference sub-pixel having the polygonal shape in a plan view, spaced apart from the first sub-pixel and the second sub-pixel by the radius, and being symmetrical to the first reference sub-pixel based on the first imaginary axis.

19. The display apparatus of claim 18, wherein the second-first corner is partially defined by a second-second curve, which is bent along a curvature of a circumference of one of the imaginary circles having a center disposed on a second-second vertex of the second reference sub-pixel.

20. The display apparatus of claim 19, wherein the second-second vertex is disposed closest to the second-first corner among vertexes of the polygonal shape of the second reference sub-pixel in a plan view.
